(19) United States
(12) Patent Application Publication
(10) Pub. No.: US 2003/0151678 A1
(43) Pub. Date: Aug. 14, 2003

(54) Camcorder combinable with a plurality of sound acquiring units

(75) Inventors: Moo-Soon Lee, Suwon-City (KR); Bum-Cheol Park, Suwon-City (KR)

Correspondence Address: STAAS & HALSEY LLP, 700 11TH STREET, NW, SUITE 500, WASHINGTON, DC, 20001, US

(73) Assignee: Samsung Electronics Co., Ltd., Suwon-City (KR)

(21) Appl. No.: 10/347,594

(22) Filed: Jan. 22, 2003

(30) Foreign Application Priority Data
Feb. 9, 2002 (KR) 2002-7750

(51) Int. Cl. H03G 3/00

(52) U.S. Cl. 348/231.4; 381/104

(57) ABSTRACT

A camcorder is combinable with a plurality of sound acquiring units. A first sound acquiring unit is provided with a plurality of sound acquiring sections, and a second sound acquiring unit is provided with at least one sound acquiring section. A main body part outputs a control signal, which variably adjusts each signal level of sound signals acquired by the sound acquiring sections provided in the first sound acquiring unit, to the first sound acquiring unit, and to receive the sound signals adjusted by the control signal from the first sound acquiring unit. The first sound acquiring unit is detachable from the main body part. With the above construction, levels of noise produced when picking up a sound signal through an internal sound acquiring unit or noise produced by a motor operating a zoom lens of the camcorder, may be minimized.

### CROSS REFERENCE TO RELATED APPLICATION

This application claims the benefit of Korean Application No. 2002-7750, filed Feb. 9, 2002, in the Korean Intellectual Property Office, the disclosure of which is incorporated herein by reference.

### BACKGROUND OF THE INVENTION

1. Field of the Invention

The present invention relates to a camcorder, and more particularly, to a camcorder capable of acquiring a sound signal through a plurality of sound acquiring units that are combinable to the camcorder.

2. Description of the Related Art

Generally, a recording/reproducing apparatus such as camcorder may record and reproduce an image and a sound, simultaneously. Upon taking a picture of images by use of the camcorder, a user may enlarge or reduce the images by use of a zoom lens of the camcorder that is capable of changing a focal distance. However, regardless of a zoom-in state of the image, sound signals near a photographer are more loudly recorded than sound signals that are recorded farther away from the photographer. Therefore, a sound matching with a reproduced image of a far-away distance is difficult to hear, while an amplified sound near the photographer is more audible.

In order to solve the above drawback, there is provided a zoom microphone to adjust a directionality of the microphone by use of a gun-type directional micro-cell having a variable length. By adjusting the directionality of the microphone using the zoom microphone, not only input images, but also input sound signals may be zoomed in.

When picking up the sound by use of the zoom microphone, an output of the sound signal may be controlled in accordance with a position of the zoom lens, according to a tele-position and wide-position of the zoom lens. In other words, if the zoom lens is positioned in the tele-position, the sound is recorded based on the directionality of the zoom microphone. With the zoom lens in the wide-position, the sound recording is focused on an internal microphone. In this case, despite the use of the zoom microphone, the output sound quality becomes closer to the sound quality acquired by the use of the internal microphone alone. However, due to noise from a deck operation during the use of the internal microphone, or the noise from a motor operation during a zooming process, the zoom microphone is unable to obtain a clean sound input as intended.

In addition, when repeatedly moving the zoom microphone from the tele-position to the wide-position while the camcorder is in use, since the clean sound recorded by the zoom microphone in the tele-position, and the sound signal containing peripheral noise recorded at the wide-position are repeatedly provided, an overall performance of the camcorder deteriorates.

### SUMMARY OF THE INVENTION

Accordingly, it is an aspect of the. present invention to provide a camcorder combinable with an external sound acquiring unit having directional and non-directional microphones, to minimize a level of noise produced from an operation of a deck in a main body part of the camcorder and noise from an operation of a motor to drive a zoom lens.

Additional aspects and advantages of the invention will be set forth in part in the description which follows and, in part, will be obvious from the description, or may be learned by practice of the invention.

The foregoing and/or other aspects of the present invention are achieved by providing a sound acquiring apparatus including a first sound acquiring section to acquire a sound with different levels of sensitivity according to a position of a sound source, a second sound acquiring section to acquire a sound with the same level of sensitivity irrespective of the position of the sound source, and a level adjusting section to variably adjust and synthesize a signal level of the sound acquired by the first sound acquiring section, and a signal level of the sound acquired by the second sound acquiring section, in accordance with a control signal inputted from an exterior, to output a synthesized sound signal.

According to an aspect of the invention, the second sound acquiring section includes a first acquiring part having a higher receiving sensitivity with respect to a first direction than a second direction, and a second acquiring part having a higher receiving sensitivity with respect to the second direction than the first direction.

The foregoing and/or other aspects of the present invention are achieved by providing a camcorder including a first sound acquiring unit having a plurality of sound acquiring sections, a second sound acquiring unit having at least one sound acquiring section, and a main body part to output a control signal, which variably adjusts each signal level of sound signals acquired by the sound acquiring sections provided in the first sound acquiring unit, to the first sound acquiring unit, and to receive the sound signals adjusted by the control signal from the first sound acquiring unit. The first sound acquiring unit is detachable from the main body part.

According to an aspect of the invention, the first sound acquiring unit includes a first sound acquiring section to acquire a sound with different levels of sensitivity according to a position of a sound source, a second sound acquiring section to acquire a sound with the same level of sensitivity irrespective of the position of the sound source, and a level adjusting section to variably adjust and synthesize a signal level of the sound acquired by the first sound acquiring section, and a signal level of the sound acquired by the second sound acquiring section, in accordance with the control signal inputted from the main body part, to output a synthesized sound signal.

According to an aspect of the invention, the first sound acquiring unit includes a first acquiring part having a higher receiving sensitivity with respect to a first direction than a second direction, and a second acquiring part having a higher receiving sensitivity with respect to the second direction than the first direction.

According to another aspect of the invention, the main body part includes a first connecting part connected to the first sound acquiring unit, and having a receiving unit to receive a first sound signal from the first sound acquiring unit. The main body part also includes a control section to output the control signal to the first sound acquiring unit. The control signal variably adjusts each signal level of the first sound signal acquired by the first sound acquiring unit according to a driving position of a zoom lens provided in the main body part.

According to yet another aspect of the invention, the main body part includes a second connecting part connected to the second sound acquiring unit, and having a receiving unit to receive a second sound signal from the second sound acquiring unit, and further includes a connection detecting section to detect whether the first and second connecting parts are connected to the first and second sound acquiring units, respectively. The control section controls the output of the first and second sound acquiring sections so that the first and second sound signals are selectively outputted when both the first and second sound signals are detected by the connection detecting section.

According to an aspect of the invention, the main body part further includes a switching section to selectively output the first and second sound signals in accordance with a selecting signal of the control section.

According to an aspect of the invention, the control section controls the switching section so that the first sound signal acquired by the first sound acquiring unit is outputted when both the first and second sound signals are detected by the connection detecting section.

According to an aspect of the invention, the control section controls the switching section so that the second sound signal acquired by the second sound acquiring unit is outputted when both the first and second sound signals are detected by the connection detecting section.

According to another aspect of the invention, the first connecting part includes a damper member to prevent vibration produced from the main body part from being transmitted to the first sound acquiring unit.

### BRIEF DESCRIPTION OF THE DRAWINGS

The above and/or other aspects, features and advantages of the present invention will become apparent and more appreciated from the following detailed description of the preferred embodiments, taken in conjunction with the accompanying drawings of which:

FIG. 1 is a view illustrating a construction of a camcorder, according to an embodiment of the present invention;

FIG. 2 is a block diagram of a camcorder, according to the present invention;

FIG. 3 is a block diagram illustrating a detailed construction of a first sound acquiring unit shown in FIG. 2;

FIG. 4 is a cross sectional view illustrating an engaged structure of a first sound acquiring unit and a first connecting part according to the present invention; and

FIG. 5 is a view illustrating an example of an operation of a level adjusting section according to the present invention, according to a driving position of a zoom lens.

### DETAILED DESCRIPTION OF THE PREFERRED EMBODIMENT

Reference will now be made in detail to the present preferred embodiments of the present invention, examples of which are illustrated in the accompanying drawings, wherein like reference numerals refer to like elements throughout.

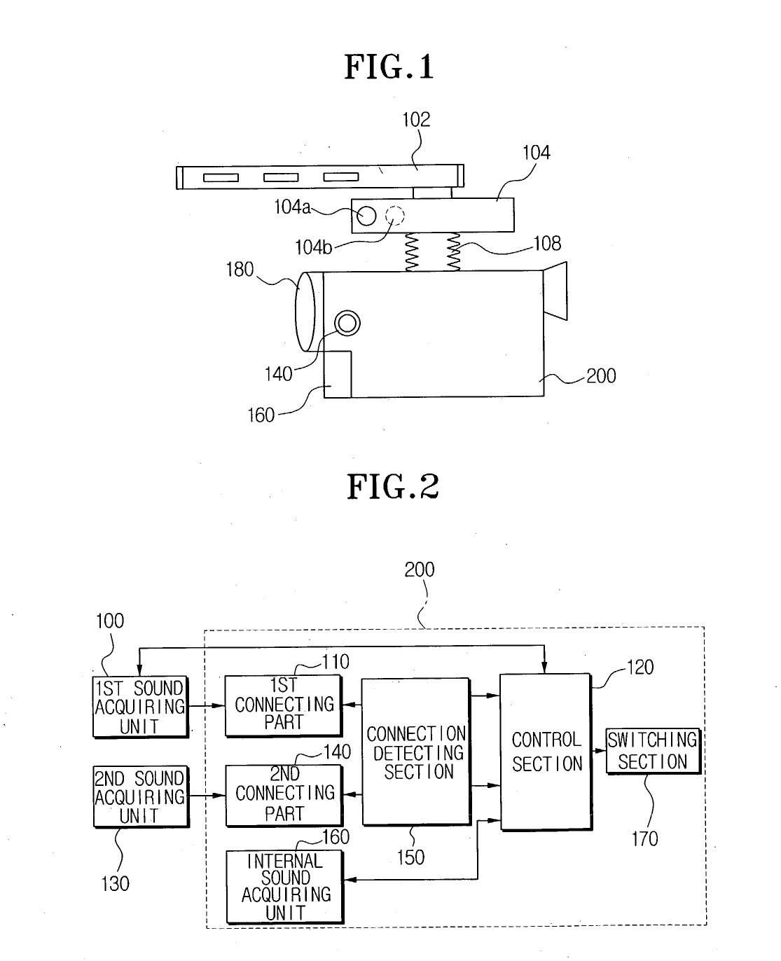

FIG. 1 is a view illustrating a construction of a camcorder, according to an embodiment of the present invention, and FIG. 2 is a block diagram of a camcorder, according to the present invention.

Referring to FIGS. 1 and 2, the camcorder includes a first sound acquiring unit 100, a second sound acquiring unit 130, and a main body part 200. The first sound acquiring unit 100 is provided with a plurality of sound acquiring sections having different directionalities. The first sound acquiring unit 100 is detachable from the main body part 200.

The main body part 200 outputs a control signal, which variably adjusts each signal level of sound signals acquired by the sound acquiring section provided in the first sound acquiring unit 100, to the first sound acquiring unit 100, and receives the sound signal adjusted by the control signal from the first sound acquiring unit 100.

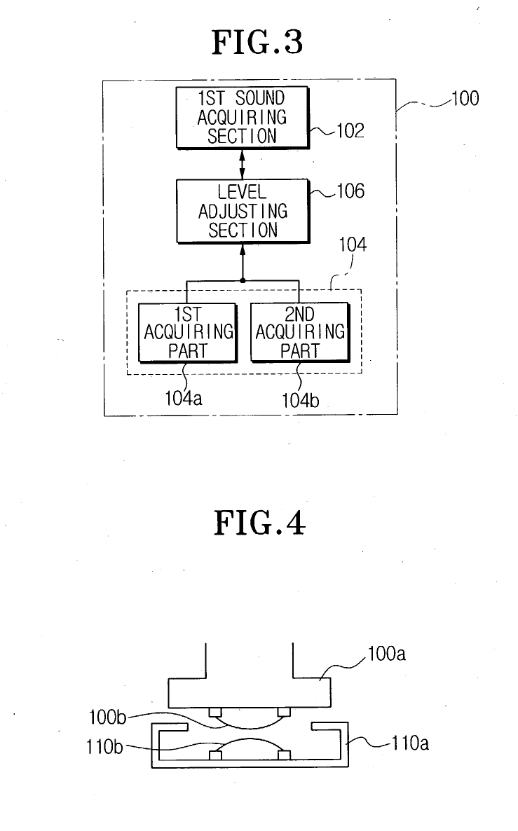

FIG. 3 is a block diagram illustrating a detailed construction of the first sound acquiring unit shown in FIG. 2.

Referring to FIG. 3, the first sound acquiring unit 100 includes a first sound acquiring section 102, a second sound acquiring section 104, and a level adjusting section 106. The first sound acquiring section 102 acquires sound with different levels of sensitivity according to a position of a sound source.

The first sound acquiring section 102 is a gun-type directional microphone that regulates a directionality of a microphone by varying a length of the microphone. It is preferable to pick up a far-off sound or a wanted sound among several sounds by use of the directional microphone. In addition, the first sound acquiring section 102 has an outer pipe, and an inner pipe located in the outer pipe in a structure that enables the adjustment of a whole length by pulling the inner pipe out of the outer pipe.

The second sound acquiring section 104 acquires sound with the same level of sensitivity irrespective of the position of the sound source. The second sound acquiring section 104 includes a first acquiring part 104a and a second acquiring part 104b. The first acquiring part 104a has a higher receiving sensitivity with respect to one direction than with respect to the other direction. For example, if the receiving sensitivity of the sound received from the left is higher than that of the sound received from the right, the first acquiring part 104a is a left microphone.

The second acquiring part 104b has the higher receiving sensitivity with respect to the other direction than with respect to the one direction. If the receiving sensitivity of the sound received from the right is higher than that of the sound received from the left, the second acquiring part 104b is a right microphone. Preferably, the first and second acquiring parts 104a and 104b are arranged symmetrically with each other on the left and right sides of the camcorder.

The second sound acquiring section 104 is a non-directional microphone, and has a fixed sensitivity with respect to sounds from omni-directions. Accordingly, it is preferable to use the non-directional microphone to pick up a natural sound or surrounding sound, as well as a targeting sound. For example, the non-directional microphone may receive a conversation between an interviewer and a plurality of interviewees during an interview. In addition, the non-directional microphone may obtain a sound signal received from omni-direction, without moving the microphone.

The level adjusting section 106 variably adjusts and synthesizes a signal level of the sound acquired by the first sound acquiring section 102, and a signal level of the sound acquired by the second sound acquiring section 104 according to a control signal inputted from a control section 120 provided in the main body part 200, to output a synthesized sound signal.

The control section 120 outputs different control signals according to a driving position of a zoom lens 180. The zoom lens 180 has a tele-function and a wide-function according to the driving position thereof. With the zoom lens 180 in the wide-position, it is possible to take a picture of a narrow indoor scene or wide outdoor scenery. With the zoom lens 180 in the tele-position, a subject positioned at a long distance may be pictured by increasing a zoom rate of the camcorder.

The control section 120 outputs the control signal to variably adjust the signal level of the sound acquired by the first sound acquiring section 102, and the signal level of the sound acquired by the second sound acquiring section 104 according to the driving position of the zoom lens 180 provided in the main body part 200.

The control section 120 outputs a first control signal to obtain a sound signal from the first sound acquiring section 102 which is the directional microphone, if the zoom lens 180 is driven to the tele-position. The control section 120 outputs a second control signal to obtain a sound signal from the second sound acquiring section 104 which is the non-directional microphone, if the zoom lens 180 is driven to the wide-position.

The level adjusting section 106 raises the signal level of the sound acquired from the first sound acquiring section 102, and lowers the signal level of the sound acquired from the second sound acquiring section 104, when the level adjusting section 106 receives the first control signal from the control section 120. The level adjusting section 106 raises the signal level of the sound acquired from the second sound acquiring section 104, and lowers the signal level of the sound acquired from the first sound acquiring section 102, when the level adjusting section 106 receives the second control signal from the control section 120.

A sound signal outputted from the level adjusting section 106 is the synthesized sound signal produced by variably adjusting and synthesizing the signal level of the sound acquired by the first sound acquiring section 102 and the signal level of the sound acquired by the second sound acquiring section 104.

The main body part 200 further includes a first connecting part 110, a second connecting part 140, a connection detecting section 150, an internal microphone 160, and a switching section 170.

The first sound acquiring unit 100 is detachable from the first connecting part 110, and the first connecting part includes a receiving unit to receive the first sound signal from the first sound acquiring unit 100.

FIG. 4 is a cross sectional view illustrating an engaged structure of a first sound acquiring unit and a first connecting part according to the present invention. Referring to FIG. 4, the first sound acquiring unit 100 is formed with a guide boss 100a detachable from the first connecting part 110. The first connecting part 110 is formed with a guide groove 110a to mount the first sound acquiring unit 100. The guide boss 100a of the first sound acquiring unit 100 is mounted onto the guide groove 110a of the first connecting part 110.

In addition, the guide boss 100a and the guide groove 110a include first and second terminals 100b and 110b, respectively, which are contacted to each other for an electrical connection.

The first connecting part 110 includes a damper member 108 to prevent a vibration, which is produced when a deck is driven or the zoom lens 180 is operated in the main body part 200, from being transmitted to the first sound acquiring unit 100. The damper member 108 is made of rubber or PVC to absorb the vibration of the main body part 200.

Although FIG. 4 shows the structure of the first sound acquiring unit 100 and the first connecting part 110 in a connected structure by way of the example, FIG. 4 is not limited to the described structure. For example, the first sound acquiring unit 100 may be mounted onto the first connecting part 110.

The second connecting part 140 is connected to the second sound acquiring unit 130, and includes a receiving unit to receive a second sound signal from the second sound acquiring unit 130. The second connecting part 140 and the second sound acquiring unit 130 include a terminal corresponding to each other to allow for an electrical connection therebetween. The second connecting part 140 includes a built-in jack to allow the second sound acquiring unit 130 to be connected to the second connecting part 140.

The connection detection section 150 detects a connection state between the first and second sound acquiring units 100 and 130 and, the control section 120 controls the switching section 170 to cause the first and second sound signals of the first and second sound acquiring units 100 and 130 to be selectively outputted.

The switching section 170 selectively outputs the first and second sound signals in accordance with a switching selecting signal of the control section 120. The switching section 170 may be achieved either through a hardware device using a logic device, or through software technology.

The internal sound acquiring unit 160 is built in the main body part 200, and generally uses a non-directional microphone of omni-directionality. The internal sound acquiring unit 160 includes a left microphone (not shown) acquiring a sound signal received from a left direction and a right microphone (not shown) acquiring a sound signal received from a right direction. If the first and second sound acquiring units 100 and 130 are not detected after the detection of the connection detecting section 150, the control section 120 controls so that the sound signal acquired by the internal sound acquiring unit 160 built-in the main body part 200 is outputted.

Generally, the first or second sound acquiring unit 100 or 130 is referred to as an external microphone, while the internal sound acquiring unit 160 is referred to as an internal microphone. If at least one external microphone is detected, the control section 120 controls so that a signal of the internal microphone is switched off so that the sound signal received from the external microphone is outputted.

If both of the first and second sound acquiring units 100 and 130 are detected by the connection detecting section 150, the control section 120 controls so that the first sound signal acquired by the first sound acquiring unit 100 may be outputted first. The switching section 170 is switched to the first sound acquiring unit 100 to output the first sound signal in accordance with the switching selecting signal of the control section 120.

The level adjusting section 106 adjusts a signal level with respect to each sound acquired by the first sound acquiring unit 100, in response to the position of the zoom lens 180 moving between the tele-position and the wide-position. If the zoom lens 180 is driven to the tele-position, the sound is picked-up by the directional microphone of the first sound acquiring section 102. If the zoom lens 180 is driven to the wide-position, the sound is picked-up by the non-directional microphone of the second sound acquiring section 104.

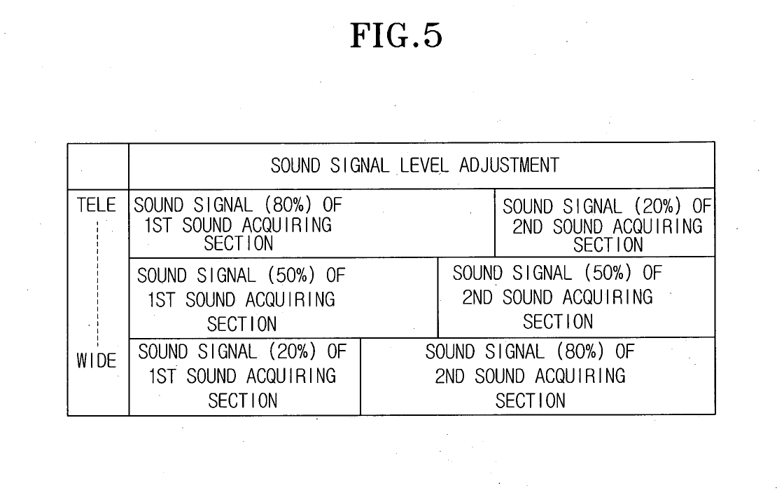

FIG. 5 is a view illustrating an example of an operation of a level adjusting section according to the present invention, according to a driving position of a zoom lens.

Referring to FIG. 5, the level adjusting section 106 adjusts the signal level with respect to sounds acquired by the first and second sound acquiring sections 102 and 104, in response to the driving position of the zoom lens 180. For example, with the zoom lens 180 in the tele-position, a level of the sound acquired by the first sound acquiring section 102 is set to 80%, and a level of the sound acquired by the second sound acquiring section 104 is set to 20%. Then, the sounds are synthesized to output a first sound signal.

When the zoom lens 180 is in the wide-position, a level of the sound acquired by the second sound acquiring section 104 is set to 80%, and a level of the sound acquired by the first sound acquiring section 102 is set to 20%. Then, the sounds are synthesized to output a second sound signal.

If both of the first and second sound acquiring units 100 and 130 are detected by the connection detecting section 150, the control section 120 controls so that the second sound signal acquired by the second sound acquiring unit 130 may be outputted first.

The switching section 170 is switched to the second sound acquiring unit 130 to output the second sound signal in accordance with the switching selecting signal of the control section 120. The second sound acquiring unit 130 may be used in an electrical connection with a wire microphone (such as a microphone used for karaoke as the second connecting part 140). In addition, the second sound acquiring unit 130 as a directional microphone may pick up a sound of a particular directionality, in accordance with the position of a sound source.

As described above, if the first and second sound acquiring units 100 and 130 are connected to the main body part 200, by picking up a sound signal from one of the first and second sound acquiring units 100 and 130, two types of sound signals are prevented from being simultaneously inputted, thereby preventing an overlapping of the sound signals.

With the camcorder combinable with a plurality of sound acquiring units according to the present invention, when connecting an external sound acquiring unit to the main body of the camcorder, an internal sound acquiring unit is switched off, and the external sound acquiring unit is operated first, thereby minimizing a level of noise produced when picking up the sound signal through the internal sound acquiring unit or the noise produced by a motor operating the zoom lens. In addition, if the plurality of sound acquiring units are coupled to the main body, simultaneous input of two types of sound signals are prevented because the sound acquiring units are operated according to a given priority. As a result, the overlapping of the signals is prevented.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A sound acquiring apparatus, comprising:
a first sound acquiring section to acquire a sound with different levels of sensitivity according to a position of a sound source;
a second sound acquiring section to acquire a sound with the same level of sensitivity irrespective of the position of the sound source; and
a level adjusting section to variably adjust and synthesize a signal level of the sound acquired by the first sound acquiring section and a signal level of the sound acquired by the second sound acquiring section in accordance with a control signal inputted from an exterior, to output a synthesized sound signal.

2. The sound acquiring apparatus as claimed in claim 1, wherein the second sound acquiring section comprises:
a first acquiring part having a higher receiving sensitivity with respect to a first direction than a second direction; and
a second acquiring part having a higher receiving sensitivity with respect to the second direction than the first direction.

3. A camcorder, comprising:
a first sound acquiring unit having a plurality of sound acquiring sections;
a second sound acquiring unit having at least one sound acquiring section; and
a main body part to output a control signal, which variably adjusts each signal level of sound signals acquired by the sound acquiring sections provided in the first sound acquiring unit, to the first sound acquiring unit, and to receive the sound signal adjusted by the control signal from the first sound acquiring unit, wherein
the first sound acquiring unit is detachable from the main body part.

4. The camcorder as claimed in claim 3, wherein the first sound acquiring unit comprises:
a first sound acquiring section to acquire a sound with different levels of sensitivity according to a position of a sound source;
a second sound acquiring section to acquire a sound with the same level of sensitivity irrespective of the position of the sound source; and
a level adjusting section to variably adjust and synthesize a signal level of the sound acquired by the first sound acquiring section and a signal level of the sound acquired by the second sound acquiring section in accordance with the control signal inputted from the main body part, to output a synthesized sound signal.

5. The camcorder as claimed in claim 4, wherein the first sound acquiring unit comprises:
a first acquiring part having a higher receiving sensitivity with respect to a first direction than a second direction; and
a second acquiring part having a higher receiving sensitivity with respect to the second direction than the first direction.

6. The camcorder as claimed in claim 3, wherein the main body part comprises:
a first connecting part connected to the first sound acquiring unit, and having a receiving unit to receive a first sound signal from the first sound acquiring unit; and
a control section to output the control signal to the first sound acquiring unit, wherein the control signal variably adjusts each signal level of the respective sound signal acquired by the first sound acquiring unit according to a driving position of a zoom lens provided in the main body part.

7. The camcorder as claimed in claim 6, wherein the main body part comprises:
a second connecting part connected to the second sound acquiring unit, and having a receiving unit to receive a second sound signal from the second sound acquiring unit; and
a connection detecting section to detect whether the first and second connecting parts are connected to the first and second sound acquiring units, respectively, wherein
the control section controls the camcorder so that the first and second sound signals are selectively outputted when both the first and second sound signals are detected by the connection detecting section.

8. The camcorder as claimed in claim 7, further comprising:
a switching section to selectively output the first and second sound signals in accordance with a selecting signal of the control section.

9. The camcorder as claimed in claim 8, wherein the control section controls the switching section so that the first sound signal acquired by the first sound acquiring unit is outputted when both the first and second sound signals are detected by the connection detecting section.

10. The camcorder as claimed in claim 8, wherein the control section controls the switching section so that the second sound signal acquired by the second sound acquiring unit is outputted when both the first and second sound signals are detected by the connection detecting section.

11. The camcorder as claimed in claim 6, wherein the first connecting part comprises:
a damper member to prevent vibration produced by the main body part from being transmitted to the first sound acquiring unit.

12. The camcorder as claimed in claim 4, wherein the first sound acquiring section is a gun-type microphone to regulate a directionality thereof by varying a length of the microphone.

13. The camcorder as claimed in claim 4, wherein the second sound acquiring section is a non-directional microphone having a fixed sensitivity with respect to sounds from omni -directions, to pick up natural, surrounding, and targeting sounds.

14. The camcorder as claimed in claim 6, further comprising:
a guide boss provided in the first sound acquiring unit and detachably connected to the first connecting part; and
a guide grove provided in the first connecting part to mount the first sound acquiring unit.

15. The camcorder as claimed in claim 14, wherein the guide boss and the guide groove include first and second terminals, respectively, to electrically contact each other.

16. The camcorder as claimed in claim 3, further comprises:
an internal sound acquiring unit provided inside the main body part, and having a non-directional microphone of omni-directionality.

17. The camcorder as claimed in claim 7, wherein the control section controls the camcorder so that simultaneously input of two different types of sound signals are prevented, to prevent an overlapping of the sound signals.

18. A camcorder, comprising:
a first sound acquiring unit having a first and second sound acquiring section;
a second sound acquiring unit having at least one sound acquiring section;
a control section provided in a main body part of the camcorder to output a control signal, which variably adjusts each signal level of sound signals acquired by the sound acquiring sections provided in the first sound acquiring unit, to the first sound acquiring unit, and to receive the sound signal adjusted by the control signal from the first sound acquiring unit, wherein
the first and second sound acquiring units are detachable from the main body part and an internal sound acquiring unit is provided inside the main body part.

19. The camcorder as claimed in claim 18, wherein the second sound acquiring unit comprises:
a first acquiring part having a higher receiving sensitivity with respect to a first direction than a second direction; and
a second acquiring part having a higher receiving sensitivity with respect to the second direction than the first direction.

20. The camcorder as claimed in claim 18, further comprising:
a zoom lens having a tele-position and wide-position, wherein the control section controls the sound signals of the first sound acquiring unit according to a driving position of the zoom lens.

21. The camcorder as claimed in claim 18, wherein the control section raises the signal level of the sound signals acquired from the first sound acquiring section, and lowers the signal level of the sound signals acquired from the second sound acquiring section, when the control signal is received by the first sound acquiring section of the first sound acquiring unit.

22. The camcorder as claimed in claim 18, wherein the control section raises the signal level of the sound signals acquired from the second sound acquiring section, and lowers the signal level of the sound signals acquired from the first sound acquiring section, when the control signal is received by the second sound acquiring section of the first sound acquiring unit.

23. The camcorder as claimed in claim 18, wherein the first sound acquiring section is a directional microphone, and the second sound acquiring section is a non-directional microphone.

24. The camcorder as claimed in claim 18, further comprising:
a switching section to selectively output the sound signals acquired by the first sound acquiring unit, the second sound acquiring unit, and the internal sound acquiring unit.

25. A camcorder having a plurality of sound acquiring units, comprising:
an external sound acquiring unit detachable from a main body part of the camcorder, and having a plurality sound acquiring sections;
an internal sound acquiring unit provided inside the main body part; and
a switching section to selectively output sound signals acquired by the external sound acquiring unit and the internal sound acquiring unit.

26. The camcorder as claimed in claim 25, wherein the switching section switches the internal sound acquiring unit off when acquiring sound signals from the external sound acquiring unit, minimizing noise produced when picking up sound signals through the internal sound acquiring unit.

27. The camcorder as claimed in claim 25, further comprising:
a control section to control the camcorder so that simultaneously input of two different types of sound signals are prevented, to prevent an overlapping of the sound signals.
